(19) United States
(12) Patent Application Publication
(10) Pub. No.: US 2020/0242203 A1
(43) Pub. Date: Jul. 30, 2020

(54) COMPUTING DEVICE, SIMULATION SUPPORT DEVICE, AND NON-TRANSITORY COMPUTER READABLE MEDIUM

(71) Applicant: TOSHIBA MEMORY CORPORATION, Minato-ku (JP)

(72) Inventors: Chika TANAKA, Fujisawa (JP); Sadayuki Yoshitomi, Chuo-ku (JP)

(73) Assignee: TOSHIBA MEMORY CORPORATION, Minato-ku (JP)

(21) Appl. No.: 16/567,923

(22) Filed: Sep. 11, 2019

(30) Foreign Application Priority Data
Jan. 29, 2019 (JP) 2019-012812

(51) Int. Cl. G06F 17/50

(52) U.S. Cl. CPC G06F 17/5009; G06F 17/5068

(57) ABSTRACT

According to one embodiment, the computing device includes a modeling processing unit configured to model characteristics of selected cell transistor and to define a non-selected cell transistor as a parasitic resistance component of the selected cell transistor. The computing device further includes a computation processing unit configured to use as a parameter a distance between both ends of an active region of the selected cell transistor, and further to store threshold characteristics of the selected cell transistor present in the memory string as a parameter, and to obtain electrical characteristics of the selected cell transistor. The computing device is used for a circuit simulation of a semiconductor memory device including memory string of a plurality of cell transistors connected to one another in series in a channel direction.

### CROSS REFERENCE TO RELATED APPLICATIONS

This application is based upon and claims the benefit of priority from prior Japanese Patent Application No. P2019-012812 filed on Jan. 29, 2019, the entire contents of which are incorporated herein by reference.

### FIELD

Embodiments described herein relate generally to a computing device, a simulation support device and a non-transitory computer readable medium.

### BACKGROUND

Due to microfabrication and integration of nonvolatile semiconductor memory devices, it has been desirable to be able to reduce time and costs required for circuit simulations.

### BRIEF DESCRIPTION OF THE DRAWINGS

FIG. 1 is a perspective diagram for illustrating a memory cell array in an example (application example 1) in a nonvolatile semiconductor memory device applicable to the embodiments.

FIG. 2 is a perspective cross-sectional diagram illustrating a structure of one memory cell of the nonvolatile semiconductor memory device illustrated in FIG. 1.

FIG. 3 is an equivalent circuit diagram for illustrating one NAND cell unit of the nonvolatile semiconductor memory device illustrated to FIG. 1.

FIG. 4 is an explanatory diagram of an extraction method of parasitic resistance in a comparative example.

FIG. 5 is an explanatory diagram of an example of a one-string RC network model according to the embodiments.

FIG. 6 is an explanatory diagram of an example in which a non-selected cell is applied as a parasitic resistance component of a selected cell, in the one-string RC network model illustrated in FIG. 5.

FIG. 7 is an explanatory diagram of an example of defining a gate length in the case of applying one-transistor approximation by a string length, in the one-string RC network model illustrated in FIG. 5.

FIG. 8 is a drawing showing an example of a parameter used in the one-string RC network model illustrated in FIGS. 5 to 7.

FIG. 9 is a schematic block diagram for illustrating a simulation support device including a computing device according to the embodiments.

FIG. 10 is a flow chart showing an operation example of the simulation support device illustrated in FIG. 9.

FIG. 11 is a flow chart showing an example of a details operation of the simulation support device illustrated in FIG. 9.

FIG. 12 is a drawing for illustrating a block configuration of another example (application example 2) in a nonvolatile semiconductor memory device to be subjected to a circuit simulation in the embodiments.

FIG. 13 is a circuit diagram for illustrating a memory cell array in the nonvolatile semiconductor memory device illustrated in FIG. 12.

FIG. 14 is a perspective diagram for illustrating the memory cell array of still another example (application example 3) in the nonvolatile semiconductor memory device applicable to the embodiments.

FIG. 15 is a perspective diagram for illustrating the memory cell array of yet another example (application example 4) in the nonvolatile semiconductor memory device applicable to the embodiments.

FIG. 16 is a circuit diagram for illustrating the memory cell array in the nonvolatile semiconductor memory device illustrated in FIG. 15.

### DETAILED DESCRIPTION

Next, certain embodiments will now be described with reference to drawings. In the description of the following drawings to be explained, the identical or similar reference sign is attached to the identical or similar part. However, it should be noted that the drawings are schematic and the relation between thickness and the plane size and the ratio of the thickness of each component part differs from an actual thing. Therefore, detailed thickness and size should be determined in consideration of the following explanation. Of course, the part from which the relation and ratio of a mutual size differ also in mutually drawings is included.

Moreover, the embodiments described hereinafter merely exemplify the device and method for materializing the technical idea; and the embodiments do not specify the material, shape, structure, placement, etc. of each component part as the following. The embodiments may be changed without departing from the spirit or scope of claims.

Certain embodiments provide a computing device, a simulation support device, a non-transitory computer readable medium, each capable of reducing time and costs required for a circuit simulation.

According to one embodiment, the computing device includes a modeling processing unit configured to model characteristics of selected cell transistor and to define a non-selected cell transistor as a parasitic resistance component of the selected cell transistor. The computing device further includes a computation processing unit configured to use as a parameter a distance between both ends of an active region of the selected cell transistor, and further to store threshold characteristics of the selected cell transistor present in the memory string as a parameter, and to obtain electrical characteristics of the selected cell transistor. The computing device is used for a circuit simulation of a semiconductor memory device including memory string of a plurality of cell transistors connected to one another in series in a channel direction.

### EMBODIMENTS

### Example of 3D Structural Nonvolatile Semiconductor Memory Device (Application Example 1))

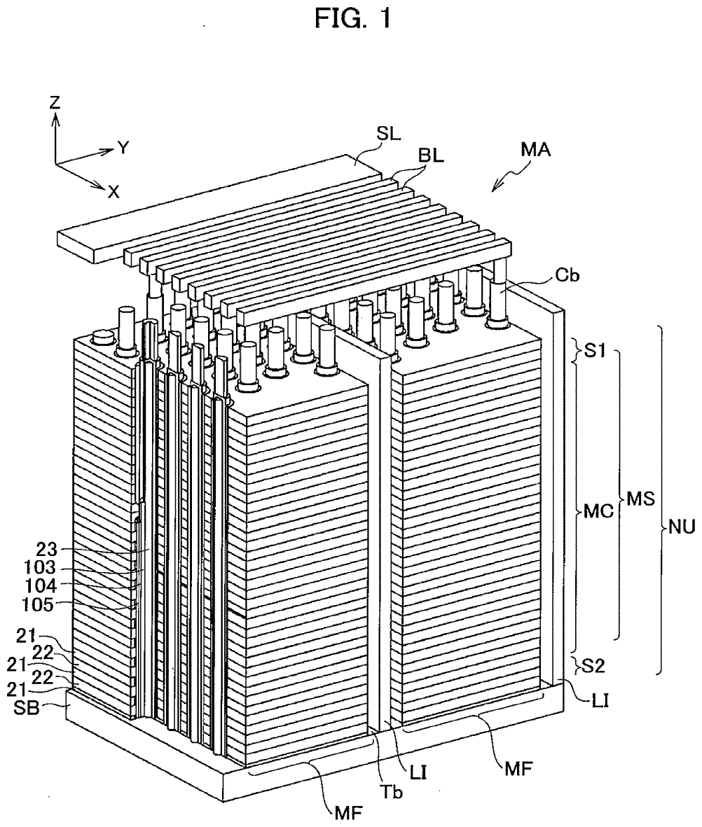

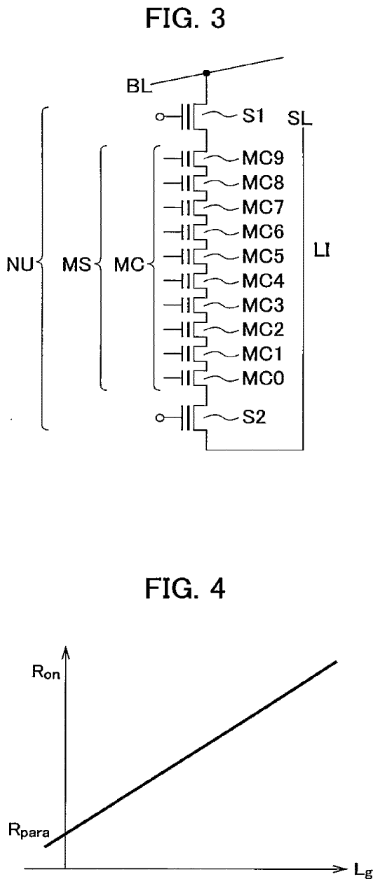

FIGS. 1 to 3 illustrate a structure of a memory cell array MA in a three-dimensional (3D) structural nonvolatile semiconductor memory device applicable to the embodiments. FIG. 1 is a perspective diagram showing a part of the structure of the memory cell array MA, FIG. 3 is a perspective cross-sectional diagram of one memory cell MC, and FIG. 3 is an equivalent circuit diagram of one NAND cell unit NU.

As shown in FIG. 1, the memory cell array MA has a structure in which insulating layers 21 and conductive layers 22 are alternately stacked on the semiconductor substrate SB, along a Z direction which is perpendicular to an upper surface of the substrate SB. The conductive layer 22 is functioned as a control gate (word line WL), a source-side select gate line, and a drain-side select gate line of the cell transistor MC (MC0 to MC9) (hereinafter, merely referred to as cell or transistor). The insulating layer 21 is arranged between the conductive layers 22 to electrically insulate the conductive layers 22. The conductive layer 22 may be composed by including poly-Si etc. to which p type impurities (boron etc.) or n-type impurities (phosphorus etc.) are added, for example.

Moreover, a semiconductor layer 23 is arranged to penetrate the stacked body of the insulating layers 21 and the conductive layers 22. The semiconductor layer 23 has its longitudinal direction along the stacking direction (the Z direction in FIG. 1), and is arranged at certain pitches in an XY plane. A tunnel insulating layer 103, a memory layer 104 including a charge accumulation layer, and a block insulating layer 105 are formed between the semiconductor layer 23 and the stacked body of the conductive layers 22 and the insulating layers 21. The memory layer 104 may be formed of a laminated structure of a charge accumulation layer such as a silicon nitride film and an oxide film such as silicon oxide film. A threshold voltage of the cell transistor MC changes in accordance with the amount of accumulation of charges to the charge accumulation layer. The cell transistor MC holds data corresponding to the threshold voltage.

The semiconductor layer 23 functions as a channel region (a body) of the cell transistor MC included in the NAND cell unit NU and a channel region of the select transistor S1 and S2. The semiconductor layers 23 are connected to the bit lines BL via contacts Cb. The bit lines BL have its longitudinal direction along the Y direction, and are arranged at a certain pitch in the X direction.

The lower end of the semiconductor layer 23 is electrically connected to the semiconductor substrate SB. The lower end of the semiconductor layer 23 is electrically connected to the source line SL via this substrate SB and a source contact LI described below. The source lines SL are arranged in the Y direction as its longitudinal direction in the same manner as the bit lines BL. Note that the stacked body of the insulating layers 21 and the conductive layers 22 in the memory cell array MA is divided into the above-mentioned memory fingers MF. A trench Tb is formed at the border of the division, and an insulating layer not illustrated is embedded in this trench Tb. In addition, the above-described source contact LI is formed to penetrate the insulating layer not illustrated. The source contact LI is connected to the semiconductor substrate SB at its lower end, and is connected to the source line SL at its upper end.

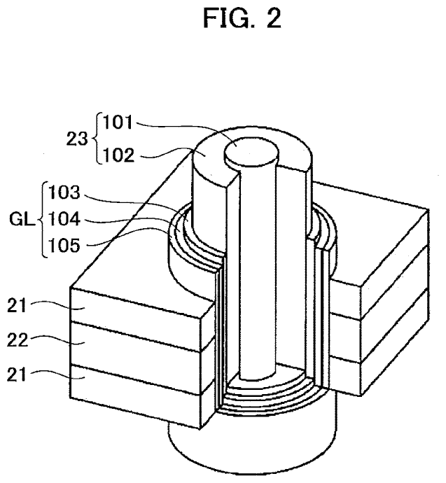

FIG. 2 shows an example of a specific structure of one cell transistor MC. The columnar semiconductor layer 23 includes an oxide film core 101, and a columnar semiconductor 102 that surrounds the periphery of the oxide film core 101. A tunnel insulating layer 103, a memory layer 104 including a charge accumulation layer, and a block insulating layer 105 are formed around the columnar semiconductor 102 to surround the columnar semiconductor 102. The tunnel insulating layer 103, the memory layer 104 and the block insulating layer 105 gate totally referred to as “a gate insulation layer GL”.

FIG. 3 is an equivalent circuit diagram of one NAND cell unit NU. In the memory cell array MA, one NAND cell unit NU includes a memory string MS, a drain-side select transistor S1, and a source-side select transistor S2. The memory string MS includes a plurality of memory cells MC. The drain-side select transistor S1 is connected between the upper end of the memory string MS and the bit line BL. The source-side select transistor S2 is connected between the lower end of the memory string MS and the source line SL. Some of the memory cells among cell transistors MC that are close to the select transistors S1 and S2 may be used as dummy cells.

### Modeling Method

There has been no modeling method for a nonvolatile semiconductor memory device having a string-shaped structure in which a plurality of cell transistors are connected to one another in series in a channel direction. Accordingly, when a modeling method is applied to a nonvolatile semiconductor memory device having a 3D structure or the like, for example, if a transistor circuit model is applied to each single cell, a net list for defining connection information becomes enormous, and time and costs required for execution of the simulation also becomes enormous.

At present, there is no transistor circuit model for a non-volatile semiconductor memory device having a 3D structure as illustrated in above-mentioned FIGS. 1 to 3, and therefore a resistor or a capacitor terminal has been used instead thereof. Accordingly, a dynamic behavior of cell transistors which is represented by coupling in a string cannot be described.

On the other hand, it is difficult to extract a parasitic resistance by means of a modeling method according to the one-transistor approximation. The parasitic resistance includes a resistance R_{poly} of a polysilicon (Poly-Si) channel, a resistance R_{BP} resulting from change of a threshold value due to background pattern (Back Pattern), and the like, for example.

More specifically, the polysilicon (poly-Si) channel has a high resistivity, and a mobility in the poly-Si is approximately 1/10 that of the bulk silicon (Si). Accordingly, it is necessary to consider the resistance R_{poly} of the poly-Si channel having the high resistivity. Moreover, it is necessary to consider the resistance component R_{BP} resulting from the change of the threshold value due to the background pattern of the charge storage layer in the memory string MS. Alternatively, a floating gate structure may be used instead of the charge storage layer.

An electric current I_{cell} (string) corresponds to an electric current which conducts through the memory string MS in which a plurality of the memory cells MC are connected to one another in series. Accordingly, if the electric current cell (string) can be extracted, the resistance R_{poly} and the resistance R_{BP} can be also be reflected.

In an extraction method of parasitic resistance according to a comparative example, as shown in FIG. 4, a parasitic resistance Rₚₐᵣₐ can be extracted by applying a limit of L_{g}→0 to the parasitic resistance Rₚₐᵣₐ from linearity of 1/Iₒₙ−L_{g}. Here, it is assumed that the mobility is not dependent on the channel length. However, in order to measure the 1/Iₒₙ-L_{g} characteristics, it is necessary to change the gate length L_{g}. For the purpose, a TEG pattern to which the gate length L_{g} is changed from a short channel to a long channel is required. It is not realistic to change the gate length L_{g} of the cell transistor in the 3D structural string since it is necessary to create a device correspondingly.

The object of the embodiments is a modeling method of a transistor which takes a high channel resistance due to a poly-Si channel different from the bulk silicon and back pattern dependency of the charge storage layer in the memory string MS.

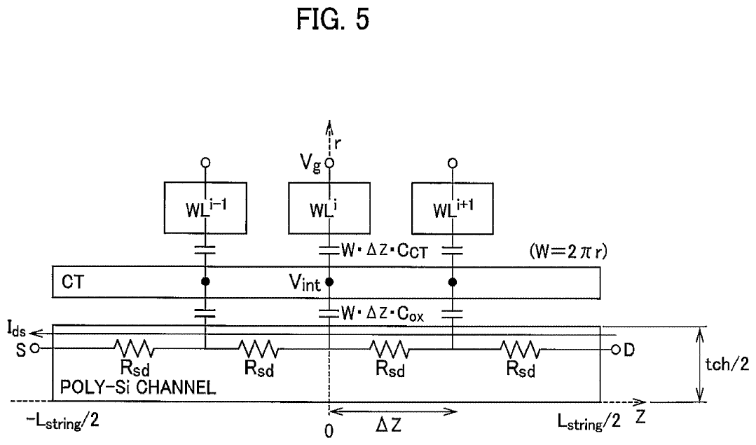

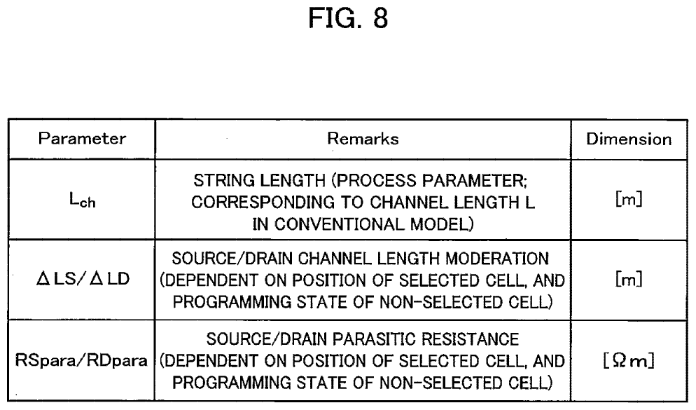

FIGS. 5 to 7 are diagrams for explaining an example of a one-string RC network model according to the embodiments. FIG. 8 shows an example of a parameter used in the one-string RC network model according to the embodiments.

The embodiments propose a modeling method by means of a one-transistor approximation, in which paying attention to a selected cell transistor WLⁱ selected by a gate voltage from among the cell transistors MC (MC0-MC9) in the memory string MS, non-selected cell transistors WLⁱ⁺¹, WLⁱ⁻¹, and the like are used as parasitic resistance components. Although WLⁱ, WLⁱ⁺¹, and WLⁱ⁻¹ originally represent respectively word lines, the cell transistors WLⁱ, WLⁱ⁺¹, and WLⁱ⁻¹ are represent in order to easily display cell transistors respectively having the word lines WLⁱ, WLⁱ⁺¹, and WLⁱ⁻¹.

More specifically, the modeling method by means of the one-transistor approximation collectively performs one-transistor approximation of the transistors in the memory string MS. Points of the approximation are as follows:
(a) The non-selected cell transistors WLⁱ⁺¹, WLⁱ⁻¹, and the like are applied as the parasitic resistance component of the selected cell transistor WLⁱ.
(b) The gate length L_{g}′ when performing the one-transistor approximation is defined by the string length L_{string}.
(c) The parasitic resistance is modeled by being regarded as “a correction to the gate length L_{g}′”.

In the one-string RC network model illustrated in FIG. 5, if the selected cell transistor corresponds to WLⁱ, the non-selected cell transistor at a drain D side adjacent to the selected cell transistor WLⁱ corresponds to WLⁱ⁺¹, and the non-selected cell transistor at a side of the source S adjacent to the selected cell transistor WLⁱ corresponds to WLⁱ⁻¹.

In order to simplify explanation, FIG. 5 schematically shows the memory string MS illustrated in FIG. 3. For example, if a cell transistor MC5 shown in FIG. 5 is the selected cell transistor WLⁱ, the non-selected cell transistor WLⁱ⁺¹ corresponds to a cell transistor MC6 shown in FIG. 3, and thereafter, the non-selected cell transistors WL¹⁺², WL¹⁺³, and WLⁱ⁺⁴ (each not illustrated) respectively correspond cell transistors MC7, MC8, and MC9 shown in FIG. 3 in a direction of the drain D. Similarly, the non-selected cell transistor WLⁱ⁻¹ corresponds to a cell transistor MC4 shown in FIG. 3, and thereafter, the non-selected cell transistor WLⁱ⁻², WLⁱ⁻³, WLⁱ⁻⁴, and WLⁱ⁻⁵ (each mot illustrated) respectively correspond to cell transistors MC3, MC2, MC1, and MC0 shown in FIG. 3 in a direction of the source S.

Moreover, I_{ds} denotes an electric current which flows from the drain D side to the source S side, and t_{ch}/2 denotes a radius (thickness) of the cylindrical poly-Si channel. In this context, t_{ch} denotes a diameter of the cylindrical poly-Si channel, and it is a model in which all poly-Si channels are depleted.

In FIG. 5, r denotes a distance in the radial direction from the center 0 of the cylindrical polysilicon channel. W=2πr denotes the channel width of the selected cell transistor WLⁱ where the distance from the center 0 of the cylindrical polysilicon channel to a gate of the selected cell transistor WLⁱ in the radial direction. An intermediate potential Vᵢₙₜ is induced in a charge storage layer CT by a gate voltage V_{g} applied to the selected cell transistor WLⁱ. A capacitor between the charge storage layer CT and the poly-Si channel is shown by WΔZCₒₓ, and a capacitor between the charge storage layers CT and WLⁱ is shown by WΔZC_{CT}, where a distance between the selected cell transistor WLⁱ and the cell transistor WLⁱ⁺¹ adjacent thereto is ΔZ. Cₒₓ denotes the capacitor per unit area between the charge storage layer CT and the poly-Si channel, and C_{CT} denotes a capacitor per unit area between the charge storage layers CT and WLⁱ. Moreover, R_{sd} denotes a poly-Si channel resistance between source and drain.

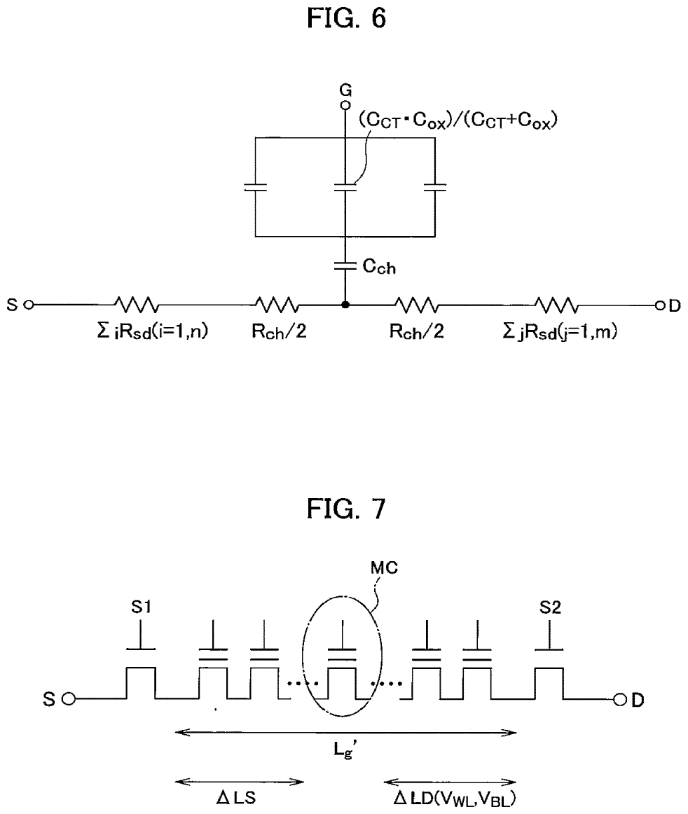

Moreover, as illustrated in FIG. 6, the non-selected cell transistor WLⁱ⁺¹ at the drain D side and the non-selected cell transistor WLⁱ⁻¹ at the source S side are applied as the parasitic resistance components of the selected cell WLⁱ.

The channel resistance of the selected cell transistor WLⁱ is represented by R_{ch}/2 at the source side and is represented by R_{ch}/2 at the drain side. The channel resistance of n-pieces of non-selected cell transistors arranged at the source side is represented by ΣᵢR_{sd} (i=1, n), and the channel resistance of m-pieces of non-selected cell transistors arranged at the drain side is represented by ΣⱼR_{sd} (j=1, n).

The capacitor component of the selected cell transistor W_{L}ⁱ is represented by the channel capacitor C_{ch}, and series capacitor (C_{CT}·Cₒₓ)/(C_{CT}+Cₒₓ) of the capacitor C_{CT} and the capacitor Cₒₓ.

Moreover, as illustrated in FIG. 7, the gate length L_{g}′ when performing the one-transistor approximation is defined by the string length L_{string}.

In FIG. 7, ΔLS denotes a channel length modulation at the source S side (Source Channel Length Modulation), and ΔLD denotes a channel length modulation at the drain D side (Drain Channel length Modulation). The ΔLS and ΔLD are dependent on a position of the selected cell MC and a writing state of the non-selected cell. Accordingly, the ΔLS becomes a function of a voltage V_{WL} applied to the word line, and the ΔLD becomes a function of a voltage V_{BL} applied to the bit line.

If the parasitic resistance component of the selected cell WLⁱ is modeled by being regarded as “a correction to the gate length L_{g}′” on the basis of the drain current expression (strong inversion), the electric current I_{ds} between the source S and the drains D can be calculated by the following equation (1):

$${I}_{ds} = {μ}_{0} W [ {C}_{ox} {V}_{ds} ( {V}_{gs} - {V}_{th} ) ] \cdot \frac{1}{{L}_{ch} [ 1 + θ ( {V}_{gs} - {V}_{th} ) ]} \qquad ( 1 )$$

where μ₀ denotes the carrier mobility, W denotes the channel width, Cₒₓ denotes the capacitor per unit area, V_{ds} denotes the voltage between drain and source, V_{gs} denotes the voltage between gate and source, and Vₜₕ denotes the threshold voltage. The L_{ch} is a channel length, and L_{ch}[1+θ(V_{gs}−Vₜₕ)] can also be regarded as a correction term with respect to the channel length L_{ch}. In this context, θ is a deterioration factor of the mobility.

Moreover, a total resistance value Rₜₒₜ (meas.) (measured value) can be calculated by the following equation (2):

$${R}_{tot}^{( meas . )} = \frac{1}{{μ}_{0} {C}_{ox} W} \cdot \frac{{L}_{ch}}{{V}_{gs} - {V}_{th}} + \frac{1}{{μ}_{0} {C}_{ox} W} \cdot {L}_{ch} \cdot θ + {R}_{sd} \qquad ( 2 )$$

The first term of the equation (2) is the channel resistance R_{ch}, and the second term+the third term is the channel resistance R_{ch} correction term. That is, a total resistance value Tₜₒₜ (meas.) can be calculated by adding the channel resistance R_{ch} correction term to the channel resistance R_{ch}. In this context, the R_{sd} is a parasitic resistance at the source S side and the drain D side (FIGS. 5 and 6), and correspond to a parameter “RSₚₐᵣₐ” and “RDₚₐᵣₐ” which are illustrated in FIG. 8.

On the other hand, a longitudinal electric field (vertical direction with respect to the channel length) ([V/L²] per unit length) can be represented by the following equation (3):

$$\frac{( {V}_{gs} - {V}_{th} ) - 1 \text{/} θ}{{L}_{ch}} \cdot \frac{1}{{t}_{ch}} = \frac{θ ( {V}_{gs} - {V}_{th} ) - 1}{θ \cdot {L}_{ch}} \cdot \frac{1}{{t}_{ch}} ↔ \frac{{V}_{gs} - {V}_{th}}{{L}_{eff}} \cdot \frac{1}{{t}_{ch}} \qquad ( 3 )$$

The left side of the equation (3) of the longitudinal electric field is a channel resistance R_{ch} correction term, and is derived from the I_{ds}=V_{ds}/Rₜₒₜ (meas.) derived from the equation (1).

More specifically, if considering that a gate voltage modulated to (V_{gs}−Vₜₕ) by 1/θ is actually (in measurement) applied with respect to the channel length L_{ch}, it becomes a gate voltage of [(V_{gs}−Vₜₕ)−1/θ]/L_{ch} per unit length.

Accordingly, the left side of the equation (3) is represented by “[(V_{gs}−Vₜₕ)−1/θ]/L_{ch}×(1/t_{ch})”.

Accordingly, an effective channel length L_{eff} of the selected cell transistor WLⁱ can be calculated by the following equation (4). In this case, it is assumed that the gate voltage is uniformly applied to the channel length L_{ch} in the longitudinal electric field per unit channel length L_{ch}.

$${L}_{eff} = \frac{- θ ( {V}_{gs} - {V}_{th} )}{1 - θ ( {V}_{gs} - {V}_{th} )} \cdot {L}_{ch} \qquad ( 4 )$$

Thus, a net list can be contracted and a simulation load can significantly be reduced, by executing the modeling by one-transistor approximation.

Moreover, it is possible to describe a dynamic behavior of the cell transistor MC which is represented by coupling in the memory string MS.

### Simulation Support Device

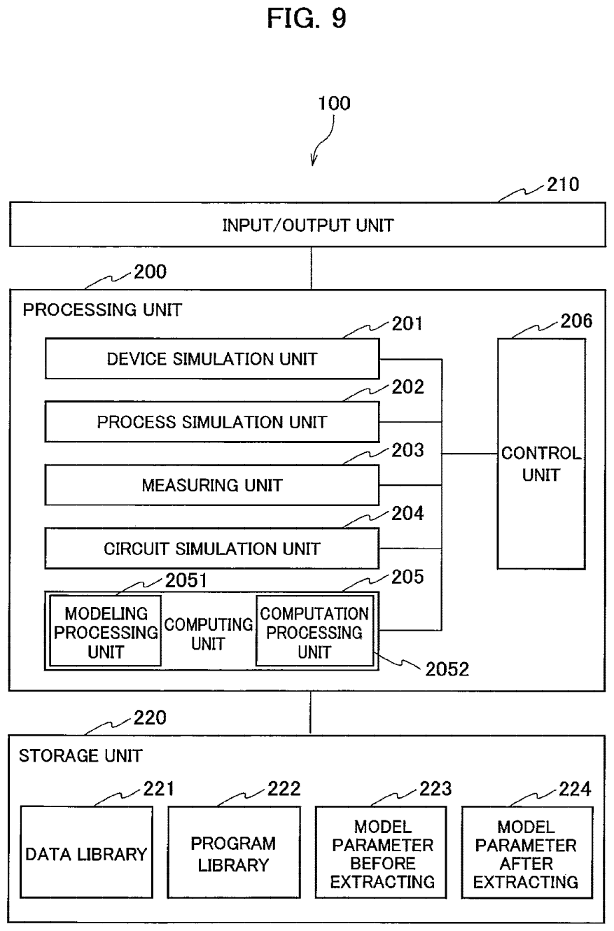

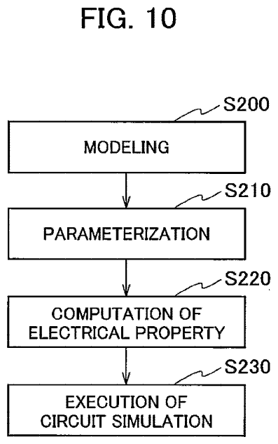

FIG. 9 schematically shows a simulation support device 100 including a computing unit (computing device) 205 according to the embodiments. Moreover, FIG. 10 is a flow chart showing an operation example of the simulation support device 100 according to the embodiments.

The simulation support device 100 according to the embodiments is simulation support device used for a circuit simulation of a semiconductor memory device including a memory string MS of a plurality of cell transistors MC connected to one another in series in a channel direction (direction of a diffusion layer). The simulation support device 100 is configured to model characteristics of a selected cell transistor MC (WLⁱ) which is selected, and to define non-selected cell transistors MC (WLⁱ⁺¹, WLⁱ⁻¹, and the like) which are not selected as a parasitic resistance component of the transistor of the selected cell MC (WLⁱ).

The simulation support device 100 uses as a parameter a distance (string length L_{string}) between both ends of an active region of the selected cell transistor MC, and also stores threshold characteristics of the selected cell transistor present in the memory string MS as a parameter, and obtains electrical characteristics of the selected cell transistor MC.

Then, the simulation support device 100 executes a circuit simulation for calculating and verifying an operation and characteristics of the circuit using the obtained electrical characteristics of the cell transistor MC.

The simulation support device 100 according to the embodiments is a device for supporting the simulation of the operation of the electronic circuit, and includes a processing unit 200, an input and output unit 210, and a storage unit 220, as illustrate in FIG. 9.

The input and output unit 210 includes an input means configured to input a circuit description, a model parameter, and the like, and an output means configured to output a simulation result, e.g. an analysis result. The input means is a keyboard, a pointing device, a recording medium, a transmission medium, or the like, and the output means is a display, a recording medium, a transmission medium, or the like, for example.

The storage unit 220 includes: a data library 221 configured to store data of the circuit description, the net list, and the like; a program library 222 configured to store a computer program and the like for causing a computer to execute a treatment operation executed by the simulation support device 100 according to the embodiments; a storage unit 223 of a model parameter before extracting Rₚₐᵣₐ configured to store a model parameter before extracting parasitic resistance Rₚₐᵣₐ; and storage unit 224 of a model parameter after extracting Rₚₐᵣₐ configured to store a model parameter after extracting the parasitic resistance Rₚₐᵣₐ.

The processing unit 200 includes a device simulation unit 201, a process simulation unit 202, a measuring unit 203, a circuit simulation unit 204, a computing unit 205, and a control unit 206.

The device simulation unit 201 is configured to input a cross-sectional structure and a three-dimensional structure of a semiconductor device, e.g. a nonvolatile semiconductor memory device, and to execute a simulation for verifying an operation of the device.

The process simulation unit 202 is configured to execute a simulation of a fabricating process (processing process) of the semiconductor device, e.g. the nonvolatile semiconductor memory device.

The measuring unit 203 is configured to measure characteristics of the semiconductor device, e.g. the nonvolatile semiconductor memory device, and to obtain a parasitic resistance component, an effective channel length L_{eff}, an electric current I_{ds} between drain and source, and the like, for example.

The computing unit (computing device) 205 includes a modeling processing unit 2051 and a computation processing unit 2052.

In the simulation support device 100 used for a circuit simulation of a semiconductor memory device including a memory string MS of a plurality of cell transistors MC connected to one another in series in a channel direction, the modeling processing unit 2051 is configured to execute a process of modeling the non-selected cell transistor WLⁱ⁺¹, WLⁱ⁻¹, and the like as a parasitic resistance component, applying the characteristics of the selected cell transistor WLⁱ selected by the gate voltage as true characteristics.

The computation processing unit 2052 uses as a parameter a distance (string length L_{string}) between both ends of an active region of the selected cell transistor MC, and also stores threshold characteristics of the selected cell transistor present in the memory string MS as a parameter in the storage unit 224 of the model parameter after extracting Rₚₐᵣₐ, and executes computation processing to obtain electrical characteristics of the selected cell transistor MC.

The circuit simulation unit 204 executes a circuit simulation for calculating and verifying an operation and characteristics of the circuit using the electrical characteristics of the cell transistor MC obtained by the computing unit 205.

The control unit 206 controls each unit, and the input and output unit 210 and the storage unit 220 in the processing unit 200.

As schematically illustrated in FIG. 10, an operation example of the simulation support device 100 according to the embodiments includes: a Step S200 of executing modeling processing; a Step S210 of executing parameterization processing; a Step S220 of executing computation processing of electrical characteristics; and a Step S230 of executing a circuit simulation.

More specifically, the operation example of the simulation support device 100 according to the embodiments includes: in the simulation support device 100 used for a circuit simulation of a semiconductor memory device including a memory string MS of a plurality of cell transistors MC connected to one another in series in a channel direction (direction of the diffusion layer), the Step S200 of executing a process of modeling the non-selected cell transistor WLⁱ⁺¹, WLⁱ⁻¹, and the like as a parasitic resistance component, applying the characteristics of the selected cell transistor WLⁱ selected by the gate voltage as true characteristics; the Step of using as a parameter a distance (string length L_{string}) between both ends of an active region of the selected cell transistor MC, and also storing threshold characteristics of the selected cell transistor present in the memory string MS as a parameter in the storage unit 224 of the model parameter after extracting Rₚₐᵣₐ, and executing computation processing to obtain electrical characteristics of the selected cell transistor MC (Step S210 of executing the parameterization processing, and Step S220 of executing the computation processing of the electrical characteristics); and the Step S230 of executing a circuit simulation for calculating and verifying an operation and characteristics of a circuit using the electrical characteristics of the selected cell transistor MC obtained by Step S220 of executing the computation processing.

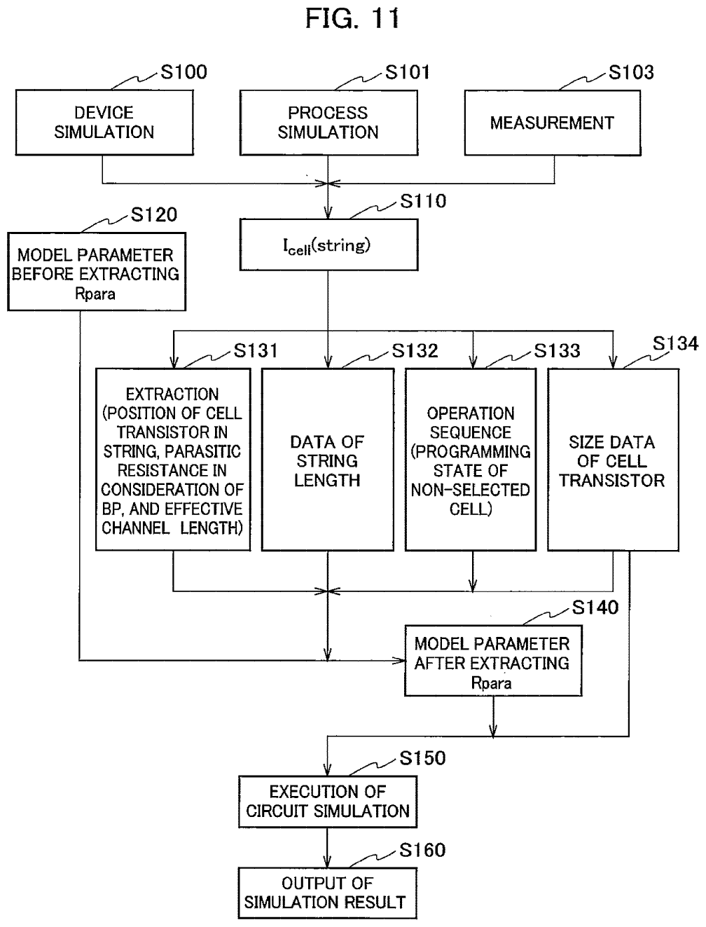

FIG. 11 is a flow chart showing an example of a details operation of the simulation support device 100 according to the embodiments.

As illustrated in FIG. 11, in the simulation support device 100 according to the embodiments: the device simulation unit 201 inputs a cross-sectional structure and a three-dimensional structure of a semiconductor device, e.g. a nonvolatile semiconductor memory device, and executes a simulation for verifying an operation of the device (Step S100); the process simulation unit 202 executes a simulation of a fabricating process (processing process) of the semiconductor device, e.g. the nonvolatile semiconductor memory device (Step S101); and the measuring unit 203 measures characteristics of the semiconductor device, e.g. the nonvolatile semiconductor memory device (Step S103) and obtains a cell current I_{cell} (string) and the like (Step S110).

Next, the computing unit 205 reads a model parameter before extracting Rₚₐᵣₐ stored in the storage unit 223 of the model parameter before extracting Rₚₐᵣₐ (Step S120).

The computing unit 205 further extracts a position in the memory string MS of the cell transistor MC, a parasitic resistance component in consideration of a background pattern, an effective channel length L_{eff} of the selected cell transistor WLⁱ, and the like, on the basis of data of the cell current I_{cell} (string) and the like which are obtained at Step S110 (Step S131).

At the same time, the computing unit 205 obtains string length L_{string} data (Step S132), an operation sequence (writing state of the non-selected cell MC) (Step S133), size data of the cell transistor MC, and the like (Step S134), to generate a model parameter (refer to FIG. 8), and generates a model parameter after extracting Rₚₐᵣₐ by reflecting them on the model parameter before extracting Rₚₐᵣₐ to be stored in the storage unit 224 of the model parameter after extracting Rₚₐᵣₐ (Step S140).

Subsequently, the circuit simulation unit 204 inputs the model parameter after extracting Rₚₐᵣₐ, the size data of the cell transistor MC, and the like obtained by the computing unit 205, executes the circuit simulation for calculating and verifying the operation and the characteristics of the circuit (Step S150), and then outputs a result of the executed circuit simulation from the output means of the input and output unit 210 (Step S160).

The processing operation illustrated in FIG. 10 or 11 may be stored in the program library 222, an external recording medium, a transmission medium, or the like as computer programs, and when the above-mentioned processing operation is executed, the programs can be read to be executed in the processing unit 200.

### Example of 3D Structural Nonvolatile Semiconductor Memory Device (Application Example 2)

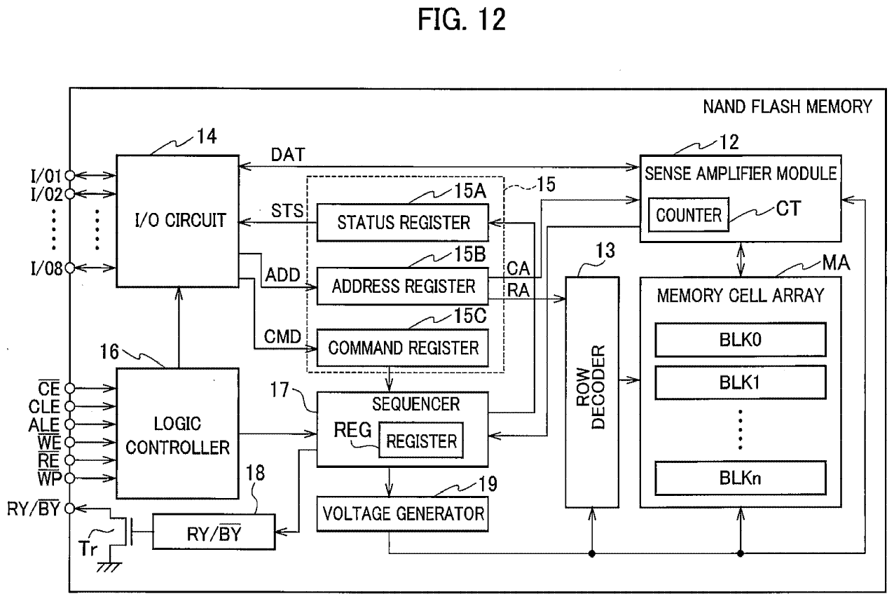

FIG. 12 shows a block diagram of a nonvolatile semiconductor memory device (application example 2) applicable to the embodiments. As illustrated in FIG. 12, the semiconductor memory device includes a memory cell array MA, a sense amplifier module 12, a row decoder 13, an input/output circuit 14, a register 15, a logic controller 16, a sequencer 17, a ready/busy control circuit 18, and a voltage generator 19.

The memory cell array MA includes blocks BLK0 to BLKn (n is a natural number equal to or greater than 1). The block BLK is a set of a plurality of nonvolatile memory cells associated with a bit line and a word line, and is, for example, an erase unit for data. Each memory cell can store data of a plurality of bits, by applying a multi-level cell (MLC) method.

The sense amplifier module 12 outputs the data DAT read from the memory cell array MA to the controller 20 through the input/output circuit 14. The sense amplifier module 12 transfers the write data DAT received from the controller 20 through the input/output circuit 14 to the memory cell array MA.

The sense amplifier module 12 also includes a counter CT, and a plurality of sense amplifier unit (not illustrated) provided for each bit line. The counter CT counts the number of on-cells of the read data and transfers the count result to the sequencer 17.

The row decoder 13 selects the word line corresponding to the memory cell to be subjected to the read operation and the write operation. Then, the row decoder 13 applies desired voltages respectively to the selected word line and the unselected word line. The register 15 includes a status register 15A, an address register 15B, and a command register 15C.

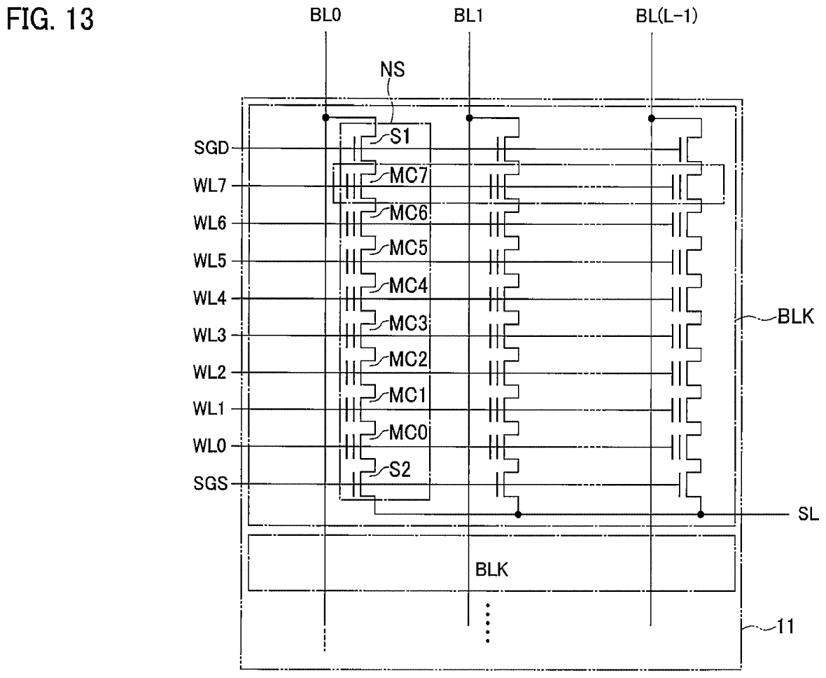

FIG. 13 is a circuit diagram of the memory cell array MA, and illustrates a detailed circuit configuration of one block BLK in the memory cell array MA. As illustrated in FIG. 13, the block BLK includes a plurality of NAND strings NS.

Each NAND string NS corresponds to one of bit lines BL0 to BL (L−1) ((L−1) is a natural number equal to or larger than 1), and includes, for example, eight cell transistors MC (MC0 to MC7) and select transistors S1 and S2. Any other number of cell transistors MC may be included in one NAND string NS.

The cell transistor MC includes a control gate and a charge storage layer, and retains data in a nonvolatile state. In addition, the cell transistors MC0 to MC7 are connected in series between the source of the select transistor S1 and the drain of the select transistor S2. The gates of the select transistor S1 and S2 in the same block BLK are commonly connected respectively to select gate lines SGD and SGS. Similarly, the control gates of the cell transistors MC0 to MC7 in the same block BLK are commonly connected respectively to word lines WL0 to WL7.

In the memory cell array MA, the drain of the select transistor S1 in any NAND string NS in the same column is commonly connected to the bit line BL. That is, the bit line BL commonly connects the NAND strings NS in the same column in a plurality of blocks BLK. Further, the sources of the plurality of select transistors S2 are commonly connected to a source line SL.

Also in the nonvolatile semiconductor memory device (application example 2) configured in this way, the circuit simulation can be executed by applying the computing device, the simulation support device, and the program, according to the embodiments.

### Example of 3D Structural Nonvolatile Semiconductor Memory Device (Application Example 3)

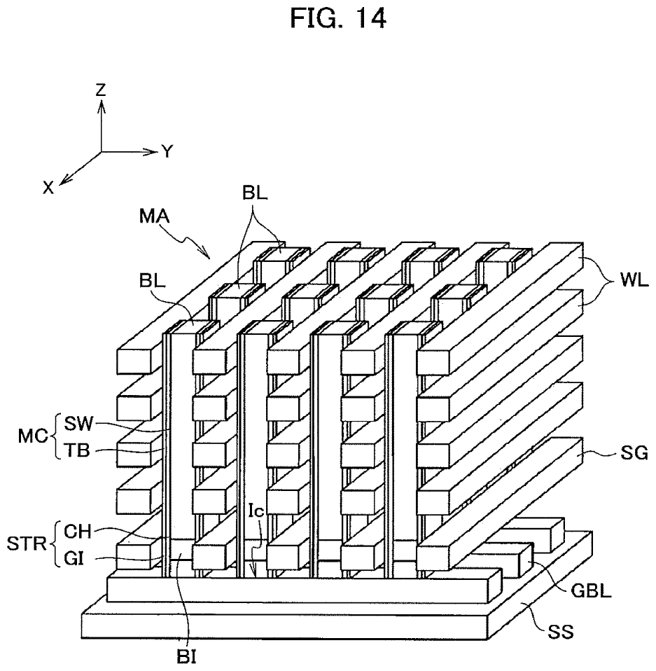

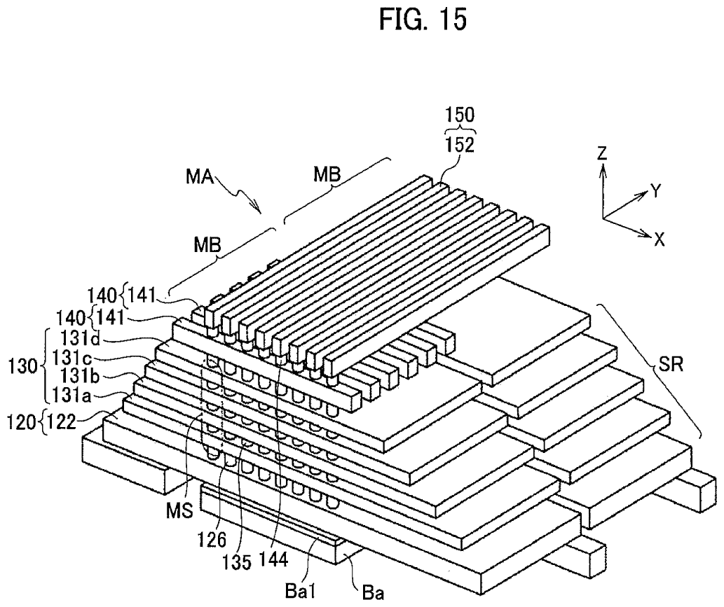

FIG. 14 illustrates a memory cell array MA of still another example (application example 3) in the nonvolatile semiconductor memory device applicable to the embodiments. Note that in FIG. 14, part of the configuration such as an interlayer insulating film between wiring lines is omitted.

As shown in FIG. 14, the memory cell array MA has a structure in which the bit line BL extends perpendicularly to a principal plane of a semiconductor substrate SS. In other words, the plurality of word lines WL are arranged in a matrix in the Y direction and the Z direction, and each extend in the X direction. The plurality of bit lines BL are arranged in a matrix in the X direction and the Y direction, and extend in the Z direction. Moreover, each of the memory cells MC is disposed in each of the intersection regions of these plurality of word lines WL and plurality of bit lines BL. In other words, the plurality of memory cells MC are arranged in a three-dimensional matrix in the X direction, the Y direction, and the Z direction. Now, the word line WL is formed by titanium nitride (TiN) or tungsten (W), for example. The bit line BL is formed of poly-Si, for example.

A plurality of the global bit lines GBL that are arranged in the X direction and extend in the Y direction are disposed between the semiconductor substrate SS and the plurality of bit lines BL. Moreover, the select transistor STR is disposed at each of lower ends of the plurality of bit lines BL. The select gate line SG that extends in the X direction is disposed between each of the select transistors STR adjacent in the Y direction. In this context, the select gate line SG is formed by, for example, titanium nitride (TiN) or tungsten (W), similarly to the word line WL. In the case of FIG. 14, one select gate line SG controls a two row portion of select transistors STR arranged in the X direction straddling the select gate line SG in the Y direction. Note that it is also possible for one select gate line SG in FIG. 14 to be divided into left and right in the Y direction and for one row portions of the select transistors STR to each be individually controlled.

Although the memory cell MC illustrated in FIG. 14 is an example of a Resistive Random Access Memory (ReRAM) using a resistance variation of a layer, a Phase-Change Memory (PCM), a Ferroelectric Random Access Memory (FeRAM), or the like can also be applied thereto.

As shown in FIG. 14, the memory cell MC is configured by a switching layer SW and a tunnel barrier layer TB that are laminated in the Y direction between the bit line BL and the word line WL. Of these, the switching layer SW is formed having as its material a transition metal oxide including an oxygen deficiency, for example. On the other hand, the tunnel barrier layer TB is formed by a metal oxide which is a material having insulating properties.

Moreover, as shown in FIG. 14, the memory cell array MA includes an insulating layer BI between the word line WL and the global bit line GBL. Moreover, the select transistor STR is configured by a channel layer CH and a gate insulating layer GI that are laminated in the Y direction between this insulating layer BI and the word line WL. Of these, the channel layer CH forms a channel, depending on a potential of the select gate line SG. In other words, in the case of the present embodiment, as shown by an arrow in FIG. 14, a current Ic flowing between the memory cell MC and the global bit line GBL ends up detouring the insulating layer BI to flow along the channel layer CH.

Also in the nonvolatile semiconductor memory device (application example configured in this way, the circuit simulation can be executed by applying the computing device, the simulation support device, and the program, according to the embodiments.

### Example of 3D Structural Nonvolatile Semiconductor Memory Device (Application Example 4)

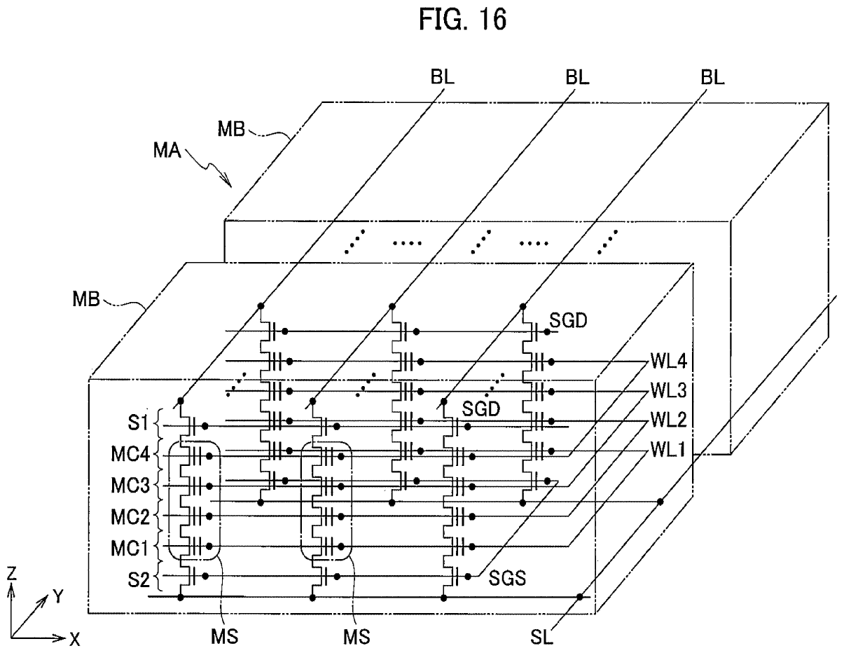

FIG. 15 illustrates a memory cell array MA of yet another example (application example 4) in the nonvolatile semiconductor memory device applicable to the embodiments. FIG. 16 is a circuit diagram for illustrating the memory cell array MA in the nonvolatile semiconductor memory device illustrated in FIG. 15.

The memory cell array MA includes a plurality of memory blocks MB. The memory blocks MB is formed on a semiconductor substrate (not shown), and arranged in a direction parallel to the Y axis.

The memory blocks MB comprises a plurality of memory strings MS, a plurality of source-side select transistors S2, and a plurality of drain-side select transistors S1. The memory string MS comprises a plurality of memory transistors (memory cells) MC1 to MC4 connected to one another in series. In FIG. 16, the memory string MS including four memory transistors MC1 to MC4 is depicted as an example, for simplicity. However, the memory string MS may include more than four memory transistors.

One of the source/drains of the drain-side select transistor S1 is connected to one end of the memory string MS (memory transistor MC4). One of the source/drains of the source-side select transistor S2 is connected to the other end of the memory string MS (memory transistor MC1). The memory strings MS are disposed in a matrix in the XY plane over the plurality of rows and the plurality of columns for each of the memory blocks MB.

With regard to the memory block MB, the control gates of the memory transistors MC1 disposed in a matrix are commonly connected to the word line WL1. Similarly, the control gates of the memory transistors MC2 are commonly connected to the word line WL2, the control gates of the memory transistors MC3 are commonly connected to the word line WL3, and the control gates of the memory transistors MC4 are commonly connected to the word line WL4.

With regard to the memory block MB, the control gates of the drain-side select transistors S1 arranged in a line along the X axis are commonly connected to a drain-side select gate line SGD. A plurality of the drain-side select gate lines SGD in one memory block MB are arranged in a line along the Y axis by a predetermined pitch. In addition, the others of source/drains of the drain-side select transistors S1 arranged in a line along the Y are commonly connected to the bit line BL. The bit line BL is formed in a manner that the bit line BL extends along the Y axis across the memory blocks MB. A plurality of bit lines BL are provided along the X axis by a predetermined pitch.

With regard to one memory block MB, the control gates of all of the source-side select transistors S2 are commonly connected to a source-side select transistor SGS. In addition, the others of the source/drains of the source-side select transistors S2 arranged along the Y axis are commonly connected to the source line SL.

As shown in FIG. 15, the memory cell array MA includes a source-side select transistor layer 120, a memory transistor layer 130, a drain-side select transistor 140 and a interconnect layers 150, which are sequentially formed on a substrate Ba, for each of the memory block cells MB.

The source-side select transistor layer 120 is a layer that functions as the source-side select transistor S2. The memory transistor layer 130 is a layer that functions as the memory string MS (memory transistors MC1 to MC4). The drain-side select transistor 140 is a layer that functions as the drain-side select transistor S1. The interconnect layers 150 are layers function as plural kinds of interconnects. The source-side select transistor layer 120 includes a source-side first insulating layer (not illustrated), a source-side conductive layer 122, and the source-side second insulating layer (not illustrated), provided one after another on the semiconductor substrate Ba. The source-side conductive layer 122 has a shape extending two dimensionally along the X axis and the Y axis (plate-like shape) under the memory block MB.

The source-side select transistor layer 120 includes a source-side pillar-shaped semiconductor layer 126. The source-side pillar-shaped semiconductor layer 126 has a pillar shape which extends along the Z axis (stacking direction). The upper surface of the source-side pillar-shaped semiconductor layer 126 is in contact with the lower surface of a pillar-shaped semiconductor layer 135. The lower surface of the source-side pillar-shaped semiconductor layer 126 is in contact with a diffusion layer Bal on the surface of the semiconductor substrate Ba. The diffusion layer Bal functions as a source line SL. The source-side pillar-shaped semiconductor layer 126 includes, for example, a polycrystalline film.

The source-side conductive layer 122 in the source-side select transistor layer 120 functions as the control gate of the source-side select transistor S2 and the source-side select gate line SGS.

The memory transistor layer 130 includes a first word line conductive layer 131a, a second word line conductive layer 131b, a third word line conductive layer 131c, a fourth word line conductive layer 131d, and the like which are provided one after another on the source-side select transistor layer 120. The first to fourth word line conductive layers 131a to 131d have a shape extending two dimensionally (plate-like shape) in a plane which is specified by the X axis and the Y axis. The first to fourth word line conductive layers 131a to 131d are divided for every memory block MB.

The drain-side select transistor layer 140 includes a drain-side conductive layer 141 provided on the memory transistor layer 130. The lower surface of the drain-side conductive layer 141 is in contact with the upper surface of the pillar-shaped semiconductor layer 135. The drain-side conductive layer 141 has a stripe shape extending along the X axis. Moreover, as shown in FIG. 15, the drain-side conductive layers 141 are arranged along the Y axis by a predetermined pitch. The drain-side conductive layer 141 includes, for example, a polycrystalline film.

The pillar-shaped semiconductor layer 135 has a pillar shape which extends along the Z axis (stacking direction). The lower surface of the pillar-shaped semiconductor layer 135 is in contact with the upper surface of the source-side pillar-shaped semiconductor layer 126. In the meantime, the upper surface of the pillar-shaped semiconductor layer 135 is in contact with the lower surface of a drain-side pillar-shaped semiconductor layer 144.

Also in the nonvolatile semiconductor memory device (application example 4) configured in this way, the circuit simulation can be executed by applying the computing device, the simulation support device, and the program, according to the embodiments.

As explained above, according to the embodiments, the net list can be contracted and the simulation load can significantly be reduced, by executing the modeling by one-transistor approximation. Accordingly, there can be provided the computing device, the simulation support device, and the program, each capable of easily and promptly verifying the operation and the characteristics of the circuit and capable of reducing the time and the costs required for the circuit simulation.

Moreover, according to the embodiments, it is possible to describe the dynamic behavior of the cell transistor which is represented by coupling in the memory string MS.

While certain embodiments have been described, these embodiments have been presented by way of examples only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, although the nonvolatile semiconductor memory device having 3D structure has been explained in the embodiments as an example, not only the example but also a semiconductor memory device having a two-dimensional (2D) structure can be applied, for example.

Such being the case, the embodiments cover a variety of embodiments and the like, whether described or not.

What is claimed is:

1. A computing device used for a circuit simulation of a semiconductor memory device including memory string of a plurality of cell transistors connected to one another in series in a channel direction, the computing device comprising:
a modeling processing unit configured to model characteristics of selected cell transistor which is selected and to define a non-selected cell transistor which is not selected as a parasitic resistance component of the selected cell transistor; and
a computation processing unit configured to use as a parameter a distance between both ends of an active region of the selected cell transistor, and further to store threshold characteristics of the selected cell transistor present in the memory string as a parameter, and to obtain electrical characteristics of the selected cell transistor.

2. The computing device according to claim 1, wherein
the modeling processing unit is configured to approximate the selected cell transistor present in the memory string to the one transistor by using the non-selected cell transistor as the parasitic resistance component of the selected cell transistor, and to define by a string length of the memory string a gate length when being approximated.

3. The computing device according to claim 2, wherein
the modeling processing unit is configured to model the parasitic resistance component by being regarded as a correction to the gate length.

4. The computing device according to claim 1, wherein
the parameter comprises an operation sequence of the non-selected cell transistor.

5. The computing device according to claim 4, wherein
the operation sequence of the non-selected cell transistor comprises a writing state of the non-selected cell transistor.

6. The computing device according to claim 1, wherein
the parameter comprises a channel length modulation at a source side and a channel length modulation at a drain side.

7. A simulation support device used for a circuit simulation of a semiconductor memory device including memory string of a plurality of cell transistors connected to one another in series in a channel direction, the simulation support device comprising:
a modeling processing unit configured to model characteristics of selected cell transistor which is selected and to define a non-selected cell transistor which is not selected as a parasitic resistance component of the selected cell transistor; and
a computation processing unit configured to use as a parameter a distance between both ends of an active region of the selected cell transistor, and further to store threshold characteristics of the selected cell transistor present in the memory string as a parameter, and to obtain electrical characteristics of the selected cell transistor

8. The simulation support device according to claim 7 further comprising
a circuit simulation unit configured to execute the circuit simulation using the obtained electrical characteristics.

9. The simulation support device according to claim 7, wherein
the modeling processing unit is configured to approximate the selected cell transistor present in the memory string to the one transistor by using the non-selected cell transistor as the parasitic resistance component of the selected cell transistor, and to define by a string length of the memory string a gate length when being approximated.

10. The simulation support device according to claim 9, wherein
the modeling processing unit is configured to model the parasitic resistance component by being regarded as a correction to the gate length.

11. The simulation support device according to claim 7, wherein
the parameter comprises an operation sequence of the non-selected cell transistor.

12. The simulation support device according to claim 11, wherein
the operation sequence of the non-selected cell transistor comprises a writing state of the non-selected cell transistor.

13. The simulation support device according to claim 7, wherein
the parameter comprises a channel length modulation at a source side and a channel length modulation at a drain side.

14. A non-transitory computer readable medium in which a computer program is stored, the computer program being executed by a computer used for a circuit simulation of a semiconductor memory device including memory string of a plurality of cell transistors connected to one another in series in a channel direction, the computer program comprising:
modelling characteristics of selected cell transistor which is selected and defining a non-selected cell transistor which is not selected as a parasitic resistance component of the selected cell transistor; and
using as a parameter a distance between both ends of an active region of the selected cell transistor, and further storing threshold characteristics of the selected cell transistor present in the memory string as a parameter, and obtaining electrical characteristics of the selected cell transistor.

15. The non-transitory computer readable medium in which the computer program is stored according to claim 14, wherein
approximating the selected cell transistor present in the memory string to the one transistor by using the non-selected cell transistor as the parasitic resistance component of the selected cell transistor, and defining by a string length of the memory string a gate length when being approximated.

16. The non-transitory computer readable medium in which the computer program is stored according to claim 15, wherein
modelling the parasitic resistance component by being regarded as a correction to the gate length.

17. The non-transitory computer readable medium in which the computer program is stored according to claim 16, wherein
the parameter comprises an operation sequence of the non-selected cell transistor.

18. The non-transitory computer readable medium in which the computer program is stored according to claim 17, wherein
the operation sequence of the non-selected cell transistor comprises a writing state of the non-selected cell transistor.

19. The non-transitory computer readable medium in which the computer program is stored according to claim 14, wherein
the parameter comprises a channel length modulation at a source side and a channel length modulation at a drain side.
